(19) United States
(12) Patent Application Publication
(10) Pub. No.: US 2014/0040686 A1
(43) Pub. Date: Feb. 6, 2014

(54) TESTING METHOD AND SEMICONDUCTOR INTEGRATED CIRCUIT TO WHICH THE SAME METHOD IS APPLIED

(71) Applicant: FUJITSU LIMITED, Kawasaki-shi (JP)

(72) Inventor: MASAHIRO YANAGIDA, Yokohama (JP)

(73) Assignee: FUJITSU LIMITED, Kawasaki-shi (JP)

(21) Appl. No.: 14/047,055

(22) Filed: Oct. 7, 2013

Related U.S. Application Data
(63) Continuation of application No. PCT/JP2011/058834, filed on Apr. 7, 2011.

(51) Int. Cl. G11C 29/10

(52) U.S. Cl. CPC G11C 29/10
USPC 714/719

(57) ABSTRACT

A method includes: writing testing data to a testing target area of the memory; reading the written data; writing the readout data to a result storage area of the memory with a first data layout; and acquiring a first comparison result by reading the data written to the result storage area and comparing the readout data with check data; rewriting the data read from the testing target area of the memory to the result storage area of the memory while changing a writing destination with a second data layout different from the first data layout within the result storage area of the memory by the testing circuit; and acquiring a second comparison result by reading the rewritten data and comparing the readout data with the check data; and specifying a defective position of the memory in accordance with the first comparison result and the second comparison result.

### CROSS-REFERENCE TO RELATED APPLICATION

This application is a continuation application of International Application PCT/JP2011/58834 filed on Apr. 7, 2011 and designated the U.S., the entire contents of which are incorporated herein by reference.

### FIELD

The embodiments discussed herein are related to a test for a semiconductor integrated circuit.

### BACKGROUND

Nowadays, a multiplicity of semiconductor integrated circuits of such a type as to be mounted with RAMs (Random Access Memories) is provided. The semiconductor integrated circuit will hereinafter be referred to as an LSI (Large Scale Integration). A test for the single LSI mounted with the RAM involves frequently using a built-in self diagnosis circuit for testing the RAM. The built-in self diagnosis circuit is called a BIST (Built In Self Test) circuit or a test control circuit.

FIG. 1 illustrates a configuration of the LSI including the test control circuit. In the configuration of FIG. 1, the test control circuit generates write data and an address serving as a write destination of the data, and writes the data to the RAM in accordance with settings given from an unillustrated LSI tester. Next, the test control circuit reads the written data from the RAM as readout data. Further, the test control circuit generates an expected value obtained when reading the data written to the RAM. Then, a comparator compares the readout data with the expected value, whereby the test control circuit generates a test result. In FIG. 1, the test result is described as error information. Then, the test control circuit outputs the error information according to a control signal of a reading circuit in accordance with, e.g., the settings of the LSI tester. An unillustrated LSI tester outside the LSI reads the error information generated in the procedure described above from the LSI. Subsequently, the LSI tester determines, based on the error information read from the test control circuit within the LSI, whether a quality of the RAM is good or not.

In a conventional testing technology of not providing the test control circuit within the LSI, all of test patterns are inputted to the LSI from the outside of the LSI, and, for example, a result of storing the inputted test patterns into the RAM is read. Accordingly, in the test of the LSI including the test control circuit described above, a period of testing time and the number of the test patters inputted can be reduced to a greater degree than by the conventional testing technology.

By the way, it may be sufficient to determine whether the quality of the RAM is good or defective in mass-production of the LSIs. Therefore, the normal test control circuit acquires information for determining whether the quality of the RAM is good or not. The information for determining whether the quality of the RAM is good or not becomes information for distinguishing between the good quality and the defective quality in terms of, e.g., a minimum information quantity. It is difficult to acquire a detailed condition of a fault from this minimum information quantity.

On the other hand, the fault is analyzed for troubleshooting a cause of the fault. Hence, the fault analysis entails obtaining items of information indicating addresses and bit counts or a state of distribution of fault portions in the RAM. Such being the case, there is used a technique of acquiring fault bit information (Fail Bit Map which will hereinafter be abbreviated to FBM) for analyzing the fault.

Generally, acquisition of the FBM requires information on all BITs of the whole addresses in the RAM. The information on all BITs of the whole addresses in the RAM, however, becomes a tremendous information quantity (data size). Supposing that the information on all BITs of the whole addresses is stored in a register, it follows that resources of a large capacity are prepared. This being the case, such a technique is taken that the register for one address is prepared for reducing a register quantity, and a result for one address is read each time one address is tested.

FIG. 2 illustrates a configuration of the test control circuit that reads the result for one address. In the case of the configuration in FIG. 2, an operation speed is delayed because of performing a reading operation each time the address advances by one, and there arises a problem that a measurement is difficult to be made at an actual speed. The “actual speed” can be also said to be, e.g., a speed of accessing the RAM when in the normal operation of the LSI. This access speed is determined by a clock frequency used for accessing the RAM within the LSI.

Proposed for making the measurement at the actual speed is a method using the RAM built in the LSI as a substitute for the register for storing the data read from the RAM. In this method, the test control circuit stores the test result of the testing target RAM in another RAM at the actual speed. FIG. 3 illustrates a configuration of the LSI that stores the test result of the testing target RAM in another RAM. In the configuration of FIG. 3, the data are read from the testing target RAM at the actual speed. The readout data are compared with the expected values by the comparator, and a result of the comparison is written to a result storage RAM.

In the case of using the result storage RAM, however, if a fault exists in the result storage RAM, there is a problem that the testing target RAM is not tested. Such being the case, a configuration of providing a standby area in the result storage RAM is proposed. FIG. 4 illustrates a configuration of the LSI to provide the standby area in the result storage RAM. With the standby area being provided in the result storage RAM, even if the fault exists in the result storage RAM, the test result can be properly retained.

### DOCUMENTS OF PRIOR ARTS

### Patent Document

[Patent document 1] Japanese Laid-open Patent Publication No. 2009-266330
[Patent document 2] Japanese Laid-open Patent Publication No. 2003-187594

### SUMMARY

One aspect of a technology of the disclosure can be exemplified by way of a testing method by which a testing apparatus tests a memory mounted on a semiconductor integrated circuit including a testing circuit. The testing method includes: writing testing data to a testing target area of the memory by a testing circuit; reading the written data; writing the readout data to a result storage area of the memory with a first data layout; and acquiring a first comparison result by reading the data written to the result storage area and comparing the readout data with check data. The testing method further includes: rewriting the data read from the testing target area of the memory to the result storage area of the memory while changing a writing destination with a second data layout different from the first data layout within the result storage area of the memory by the testing circuit; and acquiring a second comparison result by reading the rewritten data and comparing the readout data with the check data. The testing method still further includes specifying a defective position of the memory in accordance with the first comparison result and the second comparison result.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a diagram illustrating a configuration of an LSI including a test control circuit;

FIG. 2 is a diagram illustrating a configuration of the test control circuit which reads a result for one address;

FIG. 3 is a diagram illustrating a configuration of the LSI that stores a test result of a testing target RAM in another RAM;

FIG. 4 is a diagram illustrating a configuration of the LSI to provide a standby area in a result storage RAM;

FIG. 5 is a diagram illustrating an example of a RAM testing method based on BIST with a comparator;

FIG. 6 is a diagram illustrating an example of the RAM testing method based on the BIST with no comparator;

FIG. 7 is a diagram illustrating a RAM testing method according to a comparative example;

FIG. 8 is a diagram illustrating a single cell fault;

FIG. 9 is a diagram illustrating a word line fault;

FIG. 10 is a diagram depicting a bit line fault;

FIG. 11 is a diagram illustrating an example of the word line fault before an address conversion;

FIG. 12 is a diagram illustrating a processing example of the address conversion;

FIG. 13 is a diagram illustrating a processing example in a case where a result storage RAM gets into a fault;

FIG. 14 is a diagram illustrating a processing example of avoiding the bit line fault due to the data conversion;

FIG. 15 is a diagram illustrating an example of the RAM testing method based on the BIST with the comparator;

FIG. 16 is a diagram illustrating an example of a result storage RAM including an address conversion unit and a data conversion unit;

FIG. 17 is a diagram illustrating a configuration of the address conversion unit;

FIG. 18 is a diagram illustrating a configuration of the data conversion unit;

FIG. 19 is a diagram illustrating an example of the RAM fault;

FIG. 20 is a diagram illustrating a data example when reading the data from the result storage RAM by transferring a result in the testing target RAM to the result storage RAM when getting into the RAM fault;

FIG. 21 is a diagram illustrating an example of the results stored in the result storage RAM when an address invert unit conducts an address inversion;

FIG. 22 is a diagram illustrating an example of the bit line fault;

FIG. 23 is a diagram illustrating a result given by reading a write result of a test pattern to the testing target RAM and transferring the write result to the result storage RAM;

FIG. 24 is a diagram illustrating a result given when the data conversion unit replaces the data on a 2-bit basis and transfers the data;

FIG. 25 is a flowchart illustrating a processing flow of the test;

FIG. 26 is a diagram illustrating RAM testing procedures based on the BIST with no comparator;

FIG. 27 is a diagram illustrating a RAM area having rows and columns;

FIG. 28 is a diagram illustrating how RAM addresses, row numbers and column numbers are associated with each other; and

FIG. 29 is a diagram illustrating an example of inverting a bit “0”.

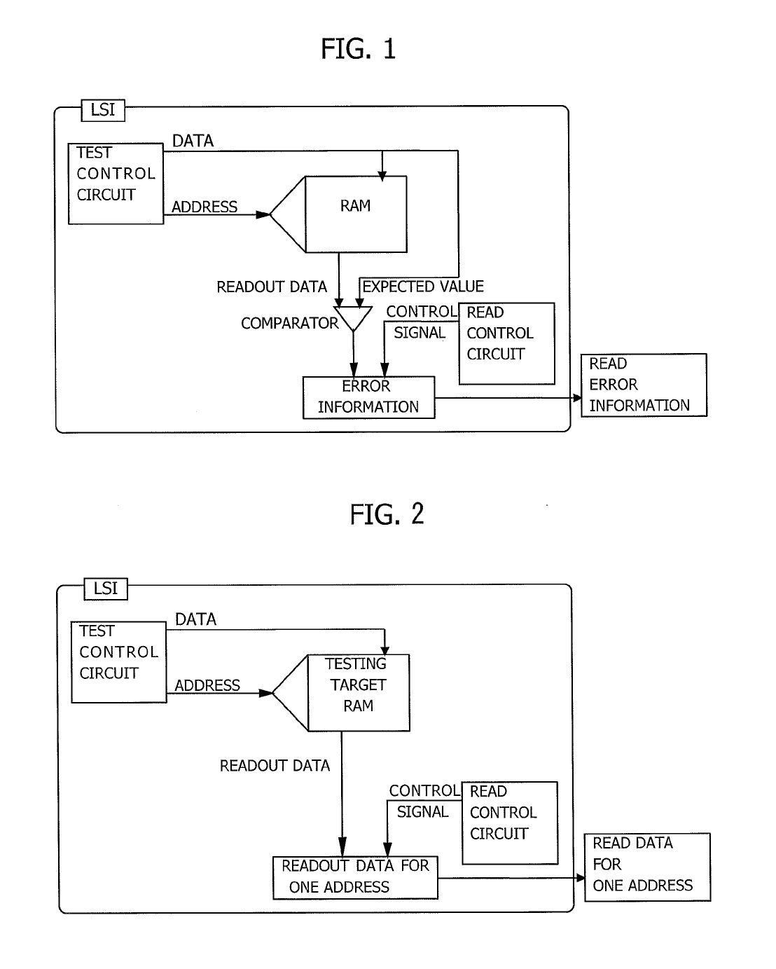

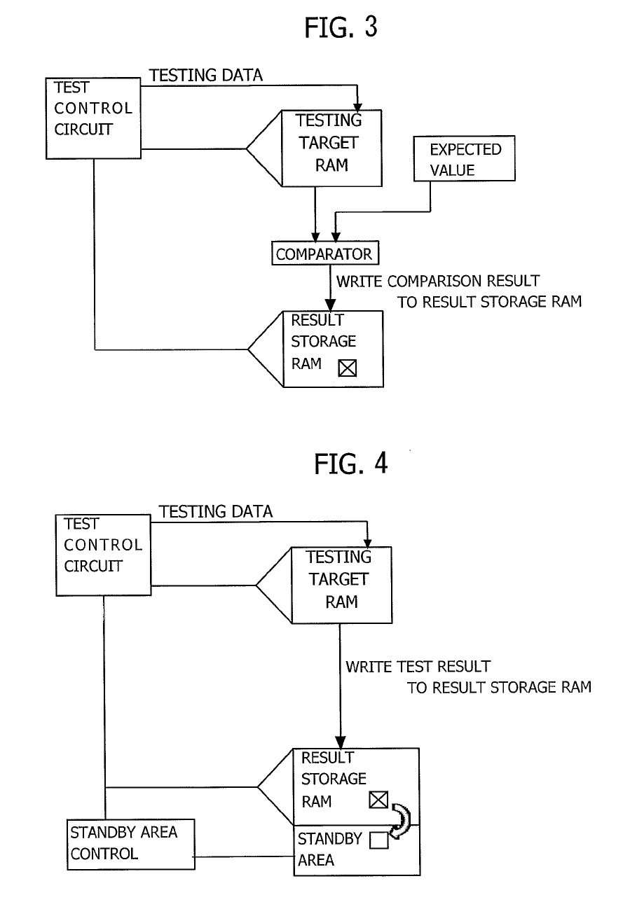

### DESCRIPTION OF EMBODIMENTS

A semiconductor integrated circuit and a method for testing the semiconductor integrated circuit according to an embodiment (which will hereinafter be simply referred to as the embodiment) will hereinafter be described by way of one aspect of the technology with reference to the drawings. A configuration of the following embodiment is an exemplification, and the present semiconductor integrated circuit and the present testing method are not limited to the configuration of the embodiment.

### Example 1

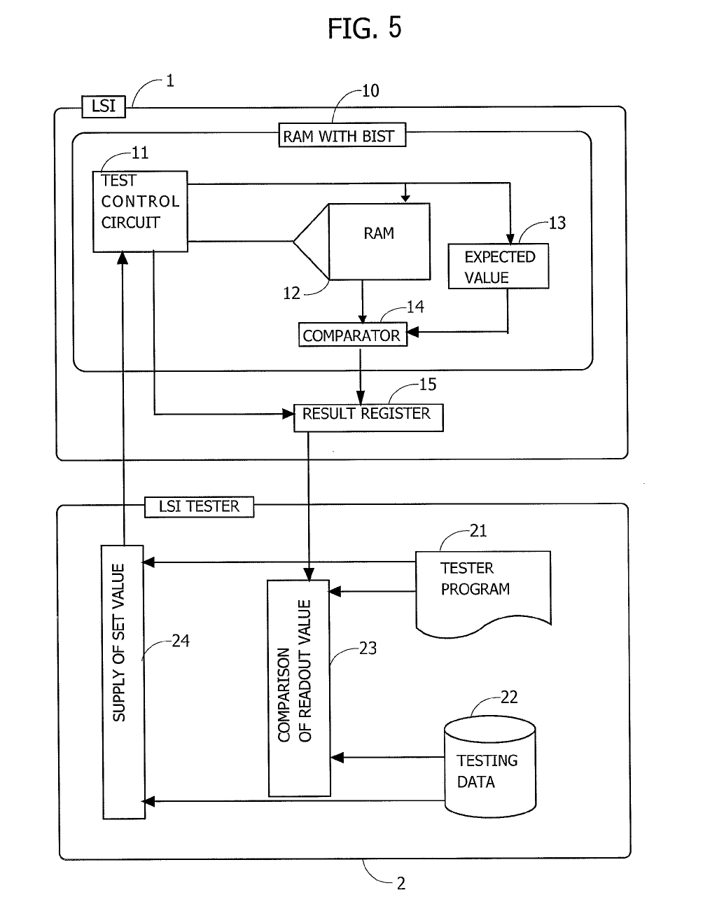

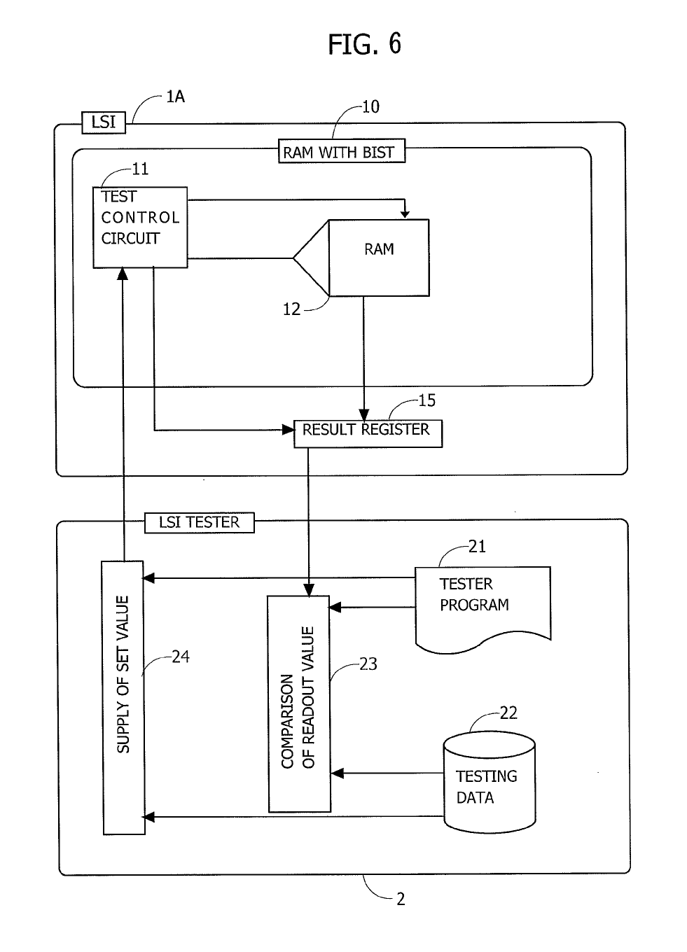

An apparatus for testing the semiconductor integrated circuit according to a first working example (Example 1) will hereinafter be described with reference to the drawings in FIGS. 5 through 14. FIGS. 5 and 6 illustrate a configuration of the apparatus used for an LSI testing method according to the example 1.

<Configurations of LSI and LSI Tester>

A measuring apparatus called an LSI tester is used for testing an LSI or measuring characteristics thereof. The LSI designed to undergo a test, a measurement, etc. by use of the LSI tester includes an interface for setting and reading values for the LSI tester. In FIGS. 5 and 6, the LSI tester and the interface with the LSI tester are depicted by two-dotted chain lines. The LSI tester is capable of setting information needed for the test within the LSI and reading a test result after finishing the test.

FIG. 5 illustrates an example of a RAM (Random Access Memory) testing method based on BIST (Built-In Self Test) with a comparator. Normally, a power source and other signals such as clocks used for the test are frequently supplied from the LSI tester. In FIG. 5, however, the power source, the clocks, etc are omitted. FIG. 5 illustrates a testing target LSI1 and an LSI tester 2. The LSI1 includes a RAM 10 with the BIST and a result register 15. Further, the RAM 10 with the BIST includes a test control circuit 11, a RAM 12, a register 13 stored with expected values and a comparator 14. The test control circuit 11 is one example of a testing circuit. The RAM 12 is one example of a memory. The expected value is one example of check data.

Herein, the testing target RAM 12 normally includes a plurality of RAM devices. In FIG. 5, however, a memory including the plurality of RAM devices is used as the RAM 12. In the following working example, a predetermined number (e.g., one piece) of RAM device(s) in the plurality of RAM devices is set as the testing target RAM. The testing target RAM is one example of a testing target area. Moreover, in the plurality of RAM devices included in the RAM 12, another RAM device having the same capacity as the testing target RAM has is set as a result storage RAM. The result storage RAM is one example of a result storage area. Accordingly, in the configuration of FIG. 5, the RAM 12 includes the testing target RAM and the result storage RAM. The RAM device is one example of a memory device.

On the other hand, the LSI tester 2 includes an unillustrated CPU and an unillustrated main storage device (main memory). The LSI tester 2 executes testing the LSI1 etc and measuring the characteristics thereof through a tester program 21 deployed in an execution-enabled manner on the main storage device. Further, the LSI tester 2 has test data 22 on the main storage device. The test data 22 may, however, be retained on an auxiliary storage device such as a hard disk device and an SSD (Solid State Drive). Moreover, the LSI tester 2 includes an interface with circuits within the LSI1 such as the test control circuit 11 and the result register 15.

The LSI tester 2 provides a setting value supply function 24 via this interface by executing the tester program. That is, the setting value supply function 24 of the LSI tester 2 acquires setting values from the test data 22 and supplies these values to the test control circuit 11. Further, the LSI tester 2 provides a readout value comparing function 23 via the interface by executing the tester program. The readout value comparing function 23 of the LSI tester 2 reads a test result, a measurement result, etc. out of the result register 15 of the LSI1.

An example of a test implementing procedure of the LSI1 will hereinafter be described.

(1) The LSI tester 2 sets, in the test control circuit 11, the test data 22 built in, e.g., the main storage device or the auxiliary storage device etc. The test data 22 contain data for generating data to be written to the testing target RAM 12, data for generating a write address of the testing target RAM 12, data for generating the expected value of the data read from the testing target RAM 12, and so on.
(2) The test control circuit 11 implements the test based on the test data being set. Herein, one RAM device included in the RAM 12 within the LSI1 shall be set as the testing target RAM, and another RAM device included in the RAM 12 within the LSI1 shall be set as the result storage RAM. The test control circuit 11 reads the data from the testing target RAM at an actual speed and stores the readout data in the result storage RAM.
(3) The test control circuit 11 reads a test result from the result storage RAM of the RAM 12, and the comparator 14 compares the test result with the expected value of the test data 22. The comparator 14 stores a comparison result in the result register 15. Note that the processing of the comparator 14 and the storage into the result register 15 may also be done at a speed slower than the actual speed. In the case of providing the comparator 14 within the LSI1 as in FIG. 5, there is obtained a minimum piece of result information such as Non-Defective Unit=0/Defective Unit=1. Therefore, the data read by the LSI tester 2 from the result register 15 has a small data size.

FIG. 6 illustrates an example of the RAM testing method based on the BIST with no comparator. An LSI1A in FIG. 6 does not, as compared with the LSI1 in FIG. 5, include the comparator 14. Accordingly, the LSI tester 2 executes comparing the test result with the expected value according to the tester program 21. The procedures of (1) to (2) are the same as those of the RAM testing method based on the BIST with the comparator in FIG. 5 and are therefore omitted.

(4) The LSI tester 2 reads the test result from the result storage RAM of the RAM 12, and compares the test result with the expected value based on the test data 22 in accordance with the tester program 21. Note that the test result may be read from the result storage RAM at a speed slower than the actual speed.

The LSI1A includes none of the comparator 14, and hence the data read from the LSI1A represent a result for a bit width of the RAM. Accordingly, a data size read by the RAM testing method based on the BIST with no comparator is larger than by the RAM testing method based on the BIST with the comparator.

Determination as to whether the comparator 14 is provided or not can be made properly corresponding to contents of the test and the configuration of the LSI. In the following Example 1, it does not mean that the comparison between the test result and the expected value is limited to any one of the case in FIG. 5 and the case in FIG. 6.

### Comparative Example

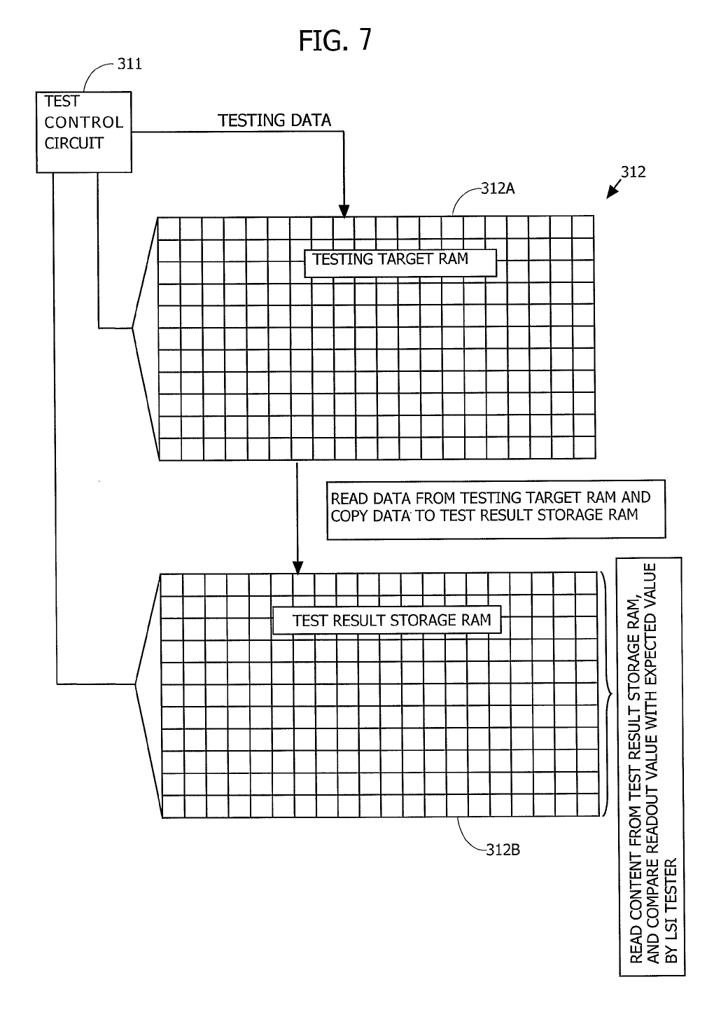

FIG. 7 illustrates a RAM testing method according to a comparative example. FIG. 7 depicts a test control circuit 311 and a RAM 312 in the LSI according to the comparative example. Further, the RAM 312 includes a testing target RAM 312A and a result storage RAM 312B. Moreover, the tester 2 is omitted in FIG. 7.

The following are procedures of implementing the test by use of the test control circuit 311.

(1) The testing data are written at the actual speed to the testing target RAM 312A from the test control circuit 311.
(2) The test control circuit 311 reads the data of the testing target RAM at the actual speed and writes the readout data to the result storage RAM 312B.
(3) The data of the result storage RAM are read to the outside of the LSI. This operation may be done at a low speed.
(4) The data of the testing data written by the test control circuit 311 are previously known. Such being the case, it may be sufficient for the tester 2 to set, as the expected values, the same values as the testing data written by the test control circuit 311. The tester 2 compares the readout data of the result storage RAM 312B with the expected values.
(5) If the data of the result storage RAM 312B are coincident with the expected values, the test result is determined to be normal.

A fault of the RAM is classified into a 0-fault (disabled from reading and writing “0”) and a 1-fault (disabled from reading and writing “1”). Therefore, the test control circuit 311 tests writing “0” and “1” to each of memory cells within the RAM 312 at least once or more times by the method described above.

By the way, it is difficult for the method in the comparative example, if an error occurs in the test result, to determine which memory, the testing target RAM 312A or the result storage RAM 312B, suffers the fault.

<Classification of Faults in RAM>

The majority of faults of the RAM are classified into the following three types.

### (1) RAM Cell Fault:

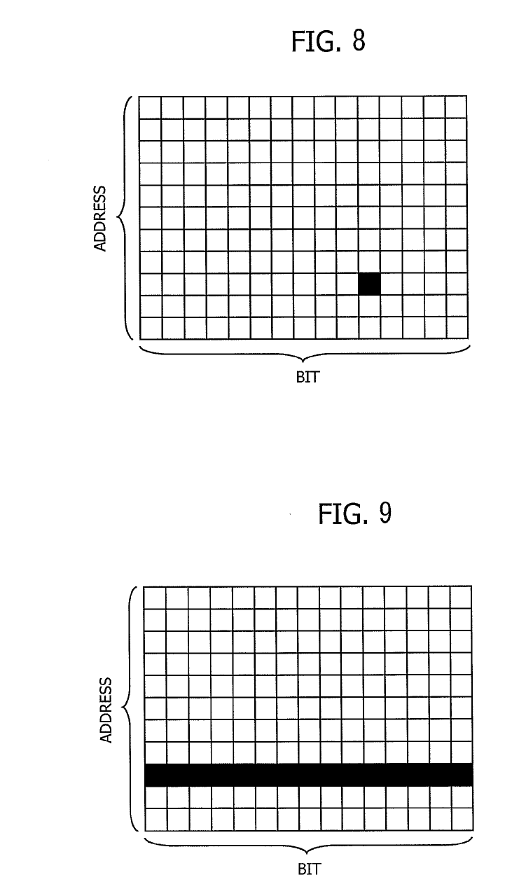

A first type of the RAM fault is a case where a cell(s) within gets into the fault (RAM cell fault). The RAM cell fault is that a single portion (single cell) undergoes the fault in many cases. FIG. 8 illustrates the single cell fault. The fault portion is the cell blotted out in black in FIG. 8. In FIG. 8, one bit on a word specified by one address suffers the fault.

### (2) Word Line Fault:

A second type of the RAM fault is a case (word line fault) in which the RAM cells get into the faults consecutively in a word-direction of the same address. The word line fault is defined as a fault in a control line for specifying the address within the RAM. The control line for specifying the address within the RAM is called a word line. The word line fault is that the single word line as a fault portion suffers the fault in many cases. FIG. 9 illustrates the word line fault. The cell blotted out in black in FIG. 9 is the fault portion. In FIG. 9, all the bits contained in one word specified by one address suffer the faults.

### (3) Bit Line Fault:

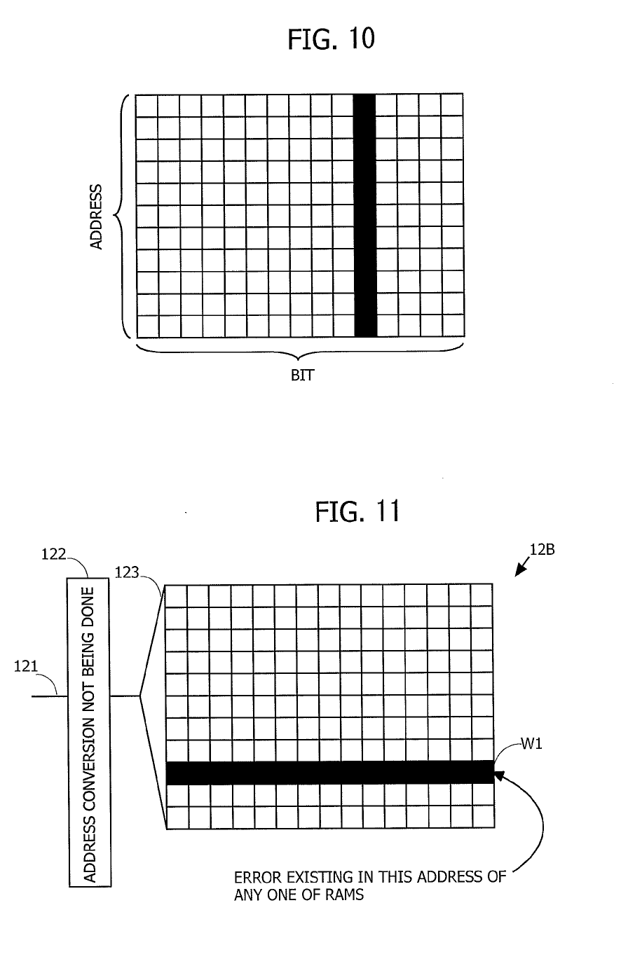

A third type of the RAM fault is a case (bit line fault) in which the RAM cells get into the faults in one bit line position in a way that extends over a plurality of words. The bit line fault is a fault in a control line for specifying a bit line position within the RAM. The control line for specifying the bit line position within the RAM is called a bit line. The bit line fault is that one bit line as the fault portion suffers the fault in many cases. FIG. 10 depicts the bit line fault. The cell blotted out in black in FIG. 10 is the fault portion. In FIG. 10, all the bits on the single bit line position specified by one bit line suffer the faults.

As for the word line fault, all the bits (whole cells) specified by one word line get into the faults in FIG. 9. Further, as for the bit line fault, all the bits (whole cells) in bit line position specified by one bit line get into the faults in FIG. 10. In the word line fault, however, all the cells specified by one word line do not necessarily get into the faults. Moreover, all the cells specified by one bit line do not necessarily get into the faults. For example, such a case may happen that the cells suffer the faults sparsely. The single cell defect is considered to be the word line fault or the bit line fault as the minimum fault (the single cell suffers the fault), in which case the fault can be processed in the way of being included in the word line fault or the bit line fault.

Hence, if the RAM faults correspond to the two types of word line fault and the bit line fault, the majority of faults can be detected and analyzed.

<Testing Method in Example 1>

(Avoidance of Word Line Fault)

According to the method in the Example 1, if the word line fault occurs in one portion, an address conversion is carried out, i.e., a conversion of the word line for selection is conducted. If using such a conversion as not to be converted into the same address before and after the address conversion, the address of the fault portion is converted into another address. Accordingly, if not in a condition where the plurality of word lines simultaneously gets into the faults, such a possibility is high as to be converted into an address corresponding to the address line undergoing none of the fault after the address conversion. Therefore, the fault portion can be avoided owing to the address conversion. FIG. 11 illustrates an example of the word line fault before the address conversion. In the example of FIG. 11, an address conversion unit 122 is provided between an address bus 121 and an address decoder 123 of the result storage RAM 12B. For instance, the address bus 121 specifies the address with a predetermined bit width. The address decoder 123 selects one address line corresponding to the specified address. The address conversion unit 122 is one example of a converting unit.

FIG. 11 illustrates a status of there being no address conversion by the address conversion unit 122. Now, it is assumed that all the bits corresponding to a word line W1 get into the faults in the status where the address conversion unit 122 does not execute the address conversion. At this point of time, it is difficult to be yet determined which RAM, the testing target RAM 12A or the result storage RAM 12B, suffers the fault.

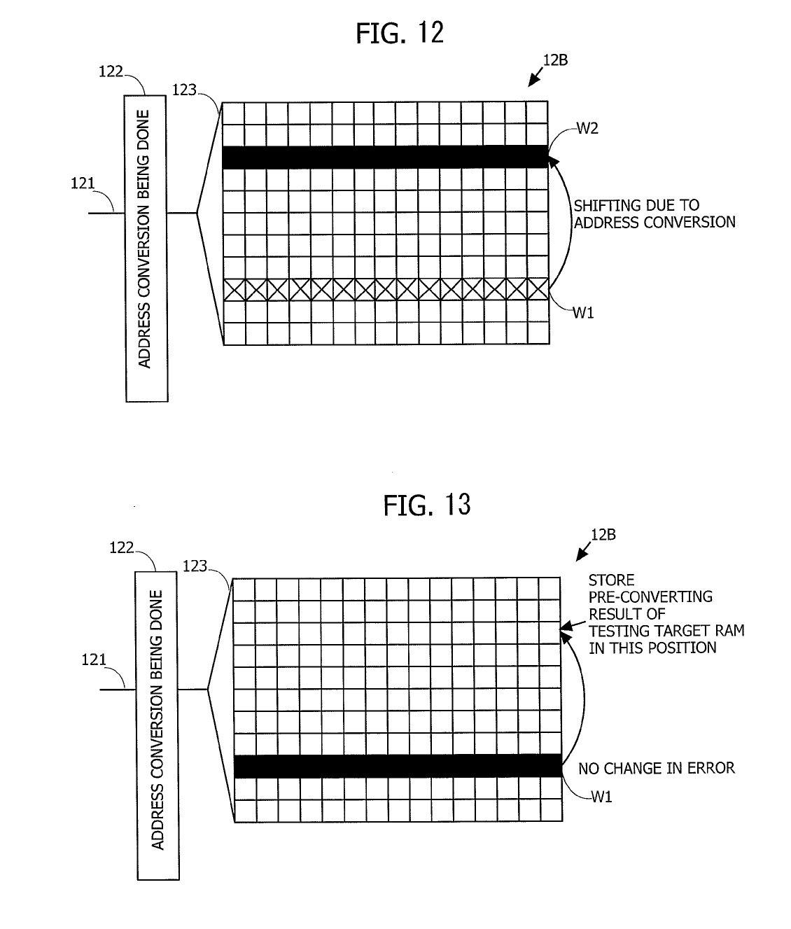

Next, the address conversion unit 122 performs the address conversion, in which state the same test as in FIG. 11 is implemented. FIG. 12 illustrates a processing example of the address conversion. It is assumed that the word line W1 remaining in an error status when carrying out no address conversion as in FIG. 12 comes to have no error in the status of there being the address conversion. Then, it is also assumed that the error position shifts to an address position of a word line W2 due to the address conversion. As in FIG. 12, if the fault portion shifts on the result storage RAM 12B depending on whether the address conversion is carried out or not, it is recognized that the fault exists in the data itself written to the result storage RAM 12B. Namely, in the example of FIG. 12, it is understood that the fault exists on the side of the testing target RAM 12A. In this case, any fault does not exist in the result storage RAM, and hence the data in the result storage RAM 12B when having no address conversion becomes the test result of the testing target RAM. A layout of the data of the result storage RAM 12B when having no address conversion is one example of a first data layout. Further, a layout of the data of the result storage RAM 12B when having the address conversion is one example of a second data layout.

FIG. 13 depicts a processing example in a case where the result storage RAM 12B gets into the fault. In FIG. 13, a position of the word line fault is fixed to the word line W1 without depending on whether there is the address conversion or not. Also in the case of having the address conversion, if the position of the word line fault remains unshifted from the status of having no address conversion, it is understood that the fault exists on the side of the result storage RAM 12B.

Moreover, the test result of the testing target RAM 12A with the fault address that is not normally acquired due to the fault of the result storage RAM 12B before the address conversion, is stored in the address position after the address conversion. If such a possibility is low that a plurality of address line faults occurs simultaneously, it may be deemed that any fault does not exist in the address position after the address conversion.

Accordingly, all the test results of the testing target RAM 12A are obtained by adding the results before the address conversion. To be specific, the test result in the address where the error occurs due to the test result with no address conversion is applied to the fault of the result storage RAM 12B and is therefore invalid. Such being the case, it may be sufficient to extract, from the test results with the address conversion, the result stored in the address into which the address (which will hereinafter be referred to as a fault address) with the fault being detected before the address conversion is converted. Then, the thus-extracted test result is replaced with the result of the fault address of the test result with no address conversion, thereby obtaining the results being all valid about the testing target RAM 12A.

### (Avoidance of Bit Line Fault)

If the bit line fault occurs in one portion, the same processing as in the case of the word line fault can be done by converting the bit line. In the case of converting the word line, the word line position is replaced. That is, the address conversions of all pieces of word data are executed to exchange the data in a way that replaces the word line position with the fault being caused before the conversion by another word line position.

On the other hand, in the case of the bit line fault, if the bit conversion is performed, the bit replacement occurs within each word. The bit replacement within each word implies a change in data value and is therefore called a data conversion. Then, such a conversion may be employed that the bit line containing the fault bit is, before and after the data conversion, converted to the same bit line position as before the conversion. If such a probability is considered low that the plurality of bit line positions simultaneously gets into the faults, such a possibility is high that the bits of the fault portion are converted to a portion with the fault not being caused after the conversion, and therefore the fault can be avoided.

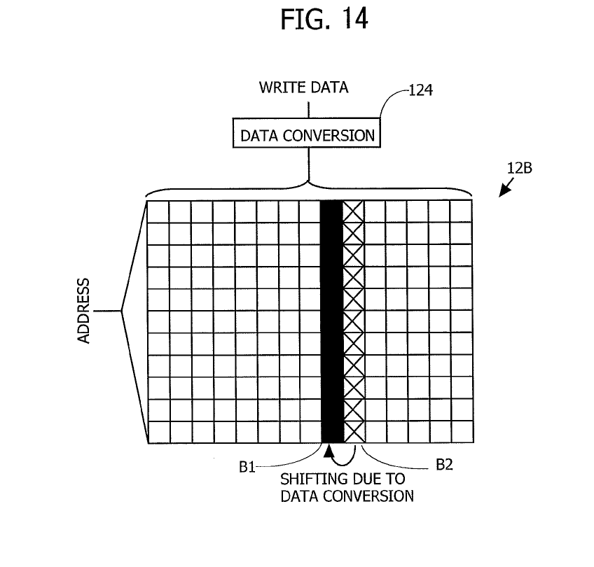

FIG. 14 illustrates a processing example of avoiding the bit line fault due to the data conversion. In the example of FIG. 14, a data conversion unit 124 is added to the bit lines of the result storage RAM 12B. The data conversion unit 124 replaces the data mutually between the bit lines via which write data are transmitted. For example, a bit line B1 and a bit line B2 are replaced with each other. The data conversion unit 124 is one example of a converting unit.

If a status of the bit line fault changes depending on whether the data conversion occurs or not, i.e., if the fault bit line position shifts, the LSI tester 2 can determine that any fault does not exist in the result storage RAM 12B. Further, the LSI tester 2 can determine that the bit line fault exists in the bit line position before the data conversion in the testing target RAM 12A.

Whereas if the status of the bit line fault does not change without depending on whether the data conversion occurs or not, i.e., if the fault bit line position does not shift, the LSI tester 2 can determine that the fault exists in the result storage RAM 12B. The LSI tester 2 acquires the bit data of the bit line position as a destination to which the fault bit line position on the result storage RAM 12B is shifted due to the data conversion, and replaces the bit data with the data in the bit line position before the data conversion in the testing target RAM 12A, thereby enabling all the testing data of the testing target RAM 12A to be acquired. The data layout of the result storage RAM 12B with no data conversion is one example of a first data layout. Further, the data layout of the result storage RAM 12B with the data conversion is one example of a second data layout.

As discussed above, according to the LSI1 in the Example 1, in the RAM 12 mounted on the LSI1, the RAM device becoming the testing target RAM 12A is combined with the RAM device becoming the result storage RAM 12B, whereby the RAM test can be implemented at the actual speed while ensuring reliability without providing a dedicated RAM device as the result storage RAM 12B or a futile RAM device as in the case of a standby storage area. Namely, it may be sufficient to perform reading and writing the data at a normal operation frequency of the LSI1 between the testing target RAM 12A and the result storage RAM 12B and also reading the data from the result storage RAM 12B at an operation frequency suited to the LSI tester 2. With this configuration, it is feasible to acquire the test result at the actual operation frequency and the test result in a status with the errors being reduced.

In this case, for instance, the result storage RAM 12B may be configured by providing at least one RAM device included in the RAM 12 with the address conversion unit 122 and the data conversion unit 124. Then, it may be sufficient that a RAM device having the same capacity as the capacity of the result storage RAM 12B provided with the address conversion unit 122 and data conversion unit 124, is selected as the testing target RAM 12A, and the test is implemented at the actual speed. Then, if the word line fault occurs, it may be sufficient that the LSI tester 2 executes the tester program 21, and it is specified whether or not the fault occurs in any one of the testing target RAM 12A and the result storage RAM 12B through the procedures illustrated in FIGS. 11-13. Moreover, if the bit line fault occurs, it may be sufficient that the LSI tester 2 executes the tester program 21, and it is specified whether or not the fault occurs in any one of the testing target RAM 12A and the result storage RAM 12B through the procedures illustrated in FIG. 14.

Furthermore, if the number of the RAM devices each becoming the testing target RAM 12A is larger than the number of RAM devices each becoming the result storage RAM 12B in the RAM 12, it may be sufficient to implement the test by sequentially replacing the RAM device becoming the testing target RAM 12A.

### Example 2

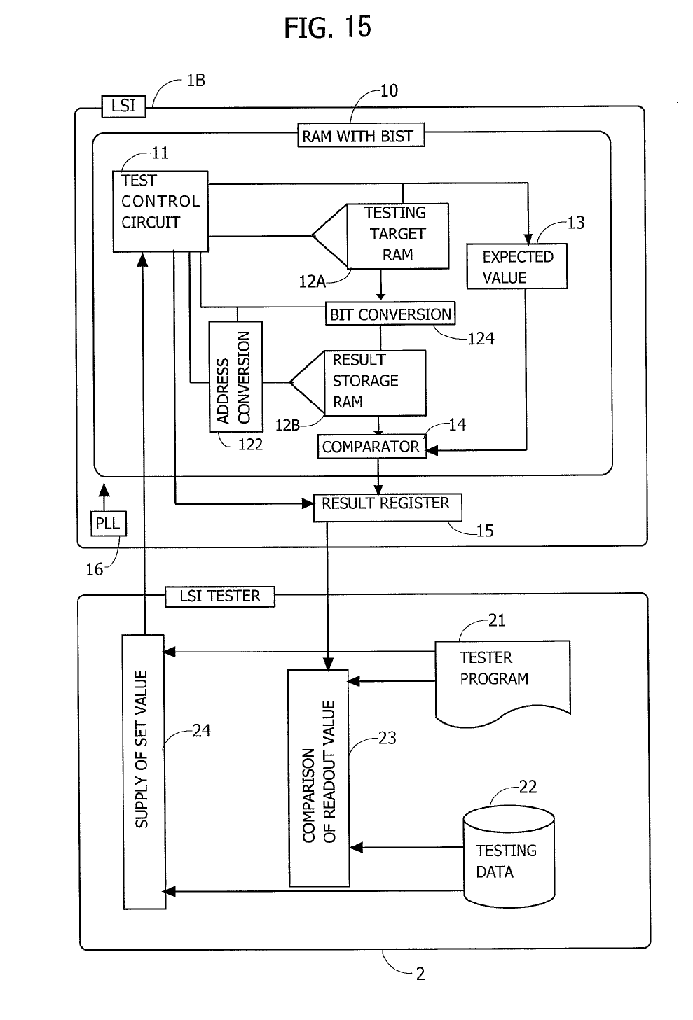

A testing apparatus for the semiconductor integrated circuit according to a second working example (Example 2) with reference to the drawings in FIGS. 15 through 25.

<Configurations of LSI and LSI Tester>

FIG. 15 illustrates an example of the RAM testing method based on the BIST with the comparator. An LSI1B in FIG. 15 is the same as the LSI1 in FIG. 5 except a point that the testing target RAM 12A, the result storage RAM 12B, the address conversion unit 122, a data conversion unit 124 and a PLL (Phase Locked Loop) 16 are explicitly depicted. This being the case, in the following Example 2, the same components as those in the Example 1 are marked with the same numerals and symbols, and their explanations are omitted.

Note that FIG. 15 depicts the testing target RAM 12A and the result storage RAM 12B. In the Example 2 also, similarly to the LSI1 in the Example 1, the LSI1B includes the plurality of RAM devices. Each of the testing target RAM 12A and the result storage RAM 12B is one of the RAM devices within the LSI1B. Further, basically, the testing target RAM 12A has the same capacity as the capacity of the result storage RAM 12B. Within the LSI1B, however, a plurality of testing target RAMs 12A may be provided. Moreover, within the LSI1B, a plurality of result storage RAMs 12B may be provided.

If the number of the RAM devices becoming the testing target RAMs 12A is larger than the number of the result storage RAMs 12B, the test may be implemented by sequentially changing the testing target RAM 12A. Moreover, in the case of providing the plurality of RAM devices each becoming the result storage RAM 12B, any one of the RAM devices may also be used as the result storage RAM 12B. Further, the test may be implemented by sequentially changing the RAM device becoming the result storage RAM 12B.

In FIG. 15, the LSI tester 2 writes the testing data 22 to the LSI1B according to the tester program 21. Furthermore, the LSI tester 2 reads values of an internal register such as the result register 15 from the LSI1B. Then, the LSI tester 2 compares the values read from the result register 15 etc with the testing data 22. Note that any inconvenience might not be caused if the LSI tester 2 writes the testing data 22 etc to the LSI1B and reads the data from the result register 15 etc of the LSI1B at a speed slower than the actual speed when in the normal operation.

The test control circuit 11 supplies the testing target RAM 10 attached with the BIST with the control signal related to the test and the testing data 22 written to the LSI tester 2. In the Example 2, the operation of the test control circuit 11 is determined based on the setting values written from the LSI tester 2.

The testing target RAM 12A performs the testing operation on the basis of the controls signal given from the test control circuit 11 and the testing data 22. The testing operation is carried out at the actual speed when in the normal operation, e.g., at a clock speed of the PLL 16. Clocks of the actual speed are supplied from, e.g., PLL 16.

The result storage RAM 12B, the address conversion unit 122 and the data conversion unit 124 transfer the data of the testing target RAM 12A to the result storage RAM 12B by the control signal given from the test control circuit 11. The data transfer is performed at the actual speed when in the normal operation of the LSI1B, e.g., at the clock speed of the PLL 16. Moreover, whether the address conversion unit 122 and the data conversion unit 124 perform the converting operation or not is controlled by the control signal given from the test control circuit 11.

The comparator 14 compares the value read out of the result storage RAM 12B with the expected value of the register 13, and stores the comparison result in the result register 15. Any inconvenience might not be caused if the operation of the comparator 14 is conducted at the speed slower than the actual speed when in the normal operation, i.e., slower than the clock speed of the PLL 16.

Hereinafter, in the Example 2, a FBM is generated for the purpose of analyzing a failure of the testing target RAM 12A. Then, in the Example 2 also, similarly to the Example 1, the fault of the result storage RAM 12B is avoided by the address conversion unit 122 and the data conversion unit 124. Note that even when any failure does not exist in any one or both of the testing target RAM 12A and the result storage RAM 12B, the procedures, which will hereinafter be described, can be carried out without problems.

Moreover, in the Example 2, the address conversion unit 122 executes the address conversion by inverting an address bit pattern. It does not, however, mean that the processing of the address conversion unit 122 is limited to the address inversion. Similarly, the data conversion unit 124 executes the data conversion by replacing the data of each word line on a 2-bit basis. It does not, however, mean that the processing of the data conversion unit 124 is limited to the data replacement on the 2-bit basis.

Further, the capacity of the RAM device included in the RAM within the LSI1B is assumed such that the address is “1024” and the bit width is “32 bits”. Accordingly, the assumption is that both of the testing target RAM 12A and the result storage RAM 12B illustrated in FIG. 15 are “1024” in address and “32 bits” in bit width. It does not, however, mean that the processes in the Example 2 given below are limited to the capacity of the RAM device, the address count (the word line count), the bit width, etc.

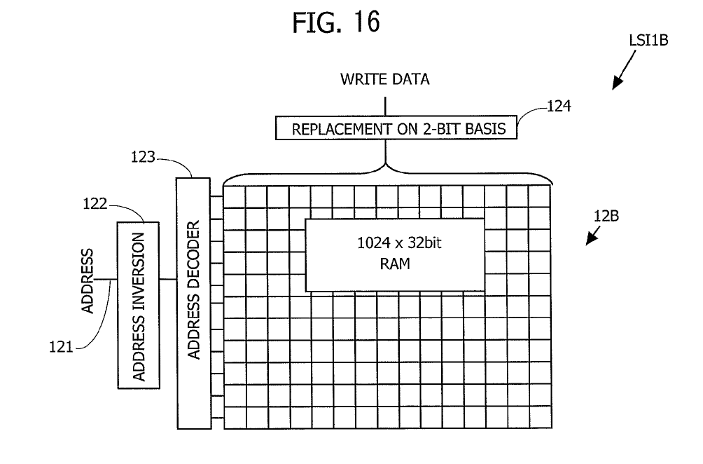

FIG. 16 illustrates an example of the result storage RAM 12B including the address conversion unit 122 and the data conversion unit 124. As in FIG. 16, the LSI1B includes an address bus 121, the address conversion unit 122 which converts address data of the address bus, an address decoder 123 which decodes the data of the address bus, and the data conversion unit 124 which converts the write data. As described above, however, the address conversion unit 122 executes the address conversion by inverting the bits of the address data. Moreover, the data conversion unit 124 converts the write data by carrying out the data replacement on the 2-bit basis.

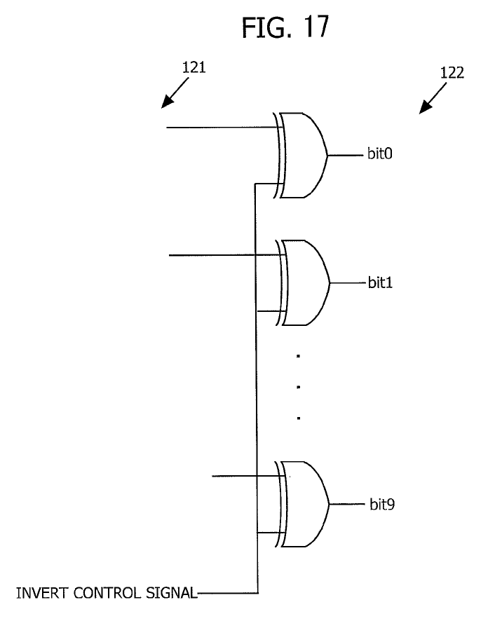

FIG. 17 illustrates a configuration of the address conversion unit 122. The address conversion unit 122 inverts respective address signals of the address bus 121 through exclusive OR. A gate which executes the exclusive OR will hereinafter be called an EXOR gate. Each EXOR gate inverts, however, the respective address signals of the address bus 121 if an invert control signal is “1”. While on the other hand, each EXOR gate does not invert the respective address signals of the address bus 121 if the invert control signal is “0”. For example, the test control circuit 11 has a control terminal for controlling the invert control signal of the address conversion unit 122 in FIG. 17 to “1” or “0”. Further, the test control circuit 11 includes an invert control register which retains an instruction of switching over the invert control signal of the address conversion unit 122 in FIG. 17 to “1” or “0”, and a value of the invert control register is set by the testing data 22 given from the LSI tester 2.

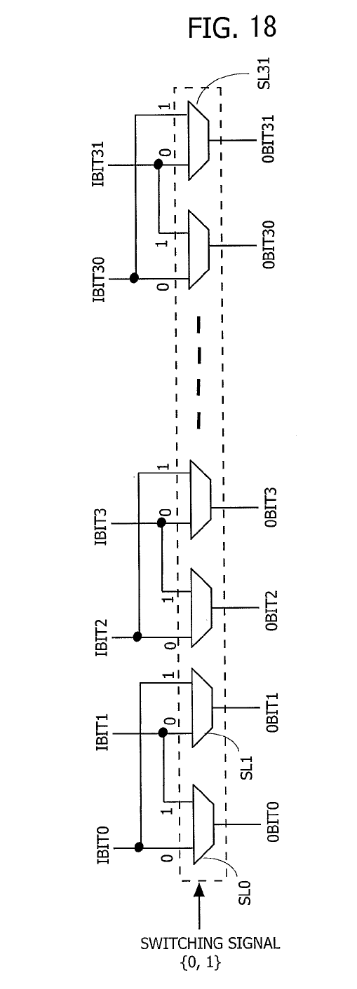

FIG. 18 illustrates a configuration of the data conversion unit 124. The data conversion unit 124 inverts the bits between, e.g., a bit “0” and a bit “1”, between a bit “2” and a bit “3” and between a bit “2k” and a bit “2k+1” in each word line. Herein, k represents an integer of 0 or larger, and a maximum value of “2k+1” indicates a most significant bit (MSB). In FIG. 18, selectors SL0-SL31 are provided for the bits “0” through “31”. Moreover, IBIT0-IBIT31 represent the bit data inputted to these selectors SL0-SL31. Further, OBIT0-OBIT31 represent the bit data output from the selectors SL0-SL31. Note that output terminals of the selectors SL0-SL31 shall be identified by codes of OBIT0-OBIT31.

In this case, for instance, the bit “0” and the bit “1” are inputted to the two selectors SL0 and SL1, respectively. The selector SL0 includes an input terminal attached with the code “0” and input terminal attached with the code “1”. When the switching signal is “0”, the input terminal attached with the code “0” of the selector SL0 is connected to the output terminal OBIT0. On the other hand, when the switching signal is “1”, the input terminal attached with the code “1” of the selector SL0 is connected to the output terminal OBIT0. Accordingly, the selector SL0 can switch over the signal connected to the output terminal between IBIT0 and IBIT1 in a way that corresponds to whether the switching signal is “0” or “1”. That is, the selector SL0 outputs IBIT0 when the switching signal is “0” and outputs IBIT1 when the switching signal is “1”. On the other hand, the selector SL1 outputs IBIT0 when the switching signal is “1” and outputs IBIT1 when the switching signal is “0”. As described above, the data conversion unit 124 replaces the bit data of each word on the 2-bit basis in accordance with the switching signal.

For example, the test control circuit 11 has a control terminal for controlling the switching signal of the data conversion unit 124 in FIG. 18 to “1” or “0”. Further, the test control circuit 11 includes an invert control register which retains an instruction of switching over the switching signal of the data conversion unit 124 in FIG. 18 to “1” or “0”, and a value of the invert control register is set by the testing data 22 given from the LSI tester 2. Next, a procedure for measuring the RAM will be described.

<Structure of Testing Data>

A test pattern used for testing the LSI1B has a structure that follows. Herein, the “test pattern” connotes the data written to the testing target RAM 12A. Note that the testing data 22 illustrated in FIG. 15 contains control data for generating the test pattern or contains data into which the test pattern is compressed. Furthermore, the testing data 22 contains control data for generating the expected value when the test pattern is read at the actual speed from the testing target RAM 12A or contains data into which the expected value is compressed.

The test pattern involves using two types of data such as a pattern “0” and a pattern “1”. The pattern “0” is that one word is data of which bits (32 bits in the Example 1) are all “0”. Further, the pattern “1” is that one word is data of which bits are all “1”.

<Testing Procedure>

A testing procedure based on the test pattern is as follows.

(1) The test control circuit 11 writes the pattern “0” to all the addresses (0-1023) of the testing target RAM 12A at the actual speed.
(2) The test control circuit 11 reads the data of the testing target RAM 12A at the actual speed and copies the data to the result storage RAM 12B without performing the address conversion and the data conversion as well. That is, the test control circuit 11 reads the data of all the addresses in the testing target RAM 12A at the actual speed from the testing target RAM 12A, and transfers the readout data to the same addresses in the result storage RAM 12B as the addresses in the testing target RAM 12A.
(3) The test control circuit 11 reads the data of the test result storage RAM 12B. The reading speed in this case might not be the actual speed. Further, the test control circuit 11 compares the readout values with the pattern “0” being the expected value by use of the comparator 14. Then, the test control circuit 11 stores the comparison result in the result register 15 in a way that deems a non-coincident portion to be the fault portion. It may be sufficient that the address with the error being detected and the comparison result of the comparator 14 are stored in the result register 15. The LSI tester 2 acquires the test result from the result register 15. Then, it may be sufficient for the LSI tester 2 to generate the FBM on the basis of the comparison result of the comparator 14.
(4) The test control circuit 11 implements the test based on the pattern “1” in the same procedures as the procedures (1)-(3), and stores the fault portion in the result register 15.
(5) The fault portion using the pattern “0” and the fault portion using the pattern “1” are added together and deemed to be the fault portion of the RAM.

Through the procedures described above, the LSI tester 2 obtains the test results of the RAMs mounted on the LSI1B. Note that the LSI tester 2 classifies the faults depending on statuses of the fault portions into the “word line fault” in the case of the faults being consecutive in the word line direction of the same address, the “bit line fault” in the case of the faults being consecutive in the direction extending over the plurality of word lines in the same bit line position and the “single cell fault” in the case of the fault in a specified address and a specified bit.

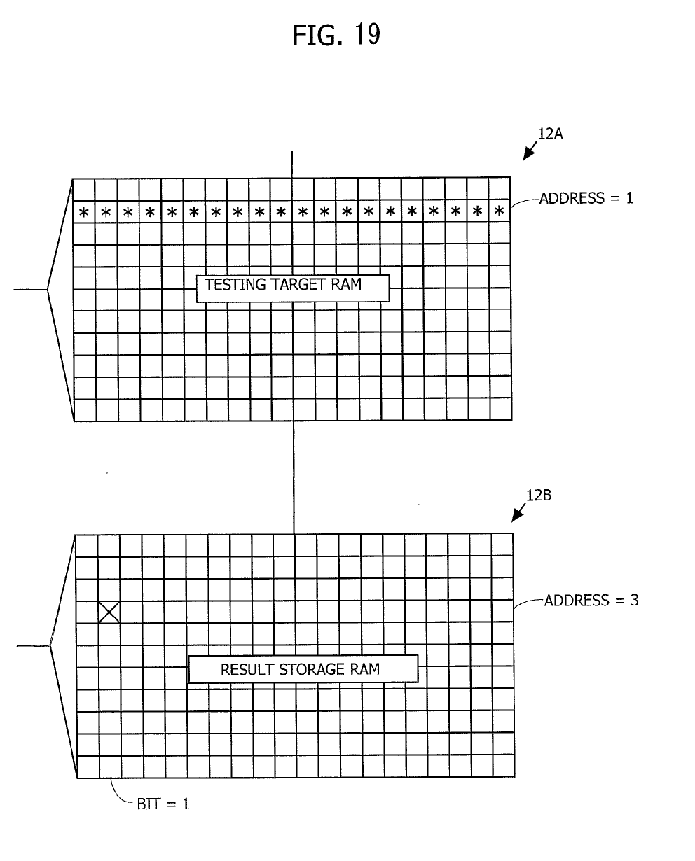

FIG. 19 illustrates an example of the RAM fault. In FIG. 19, it is assumed that the testing target RAM 12A has the word line fault in the address=1, while the result storage RAM 12B has the single cell fault in the address=3 and the bit=1. In the drawing, the position of the word line fault of the testing target RAM 12A is notated by “*”, and the position of the single cell fault of the result storage RAM 12B is notated by “X”.

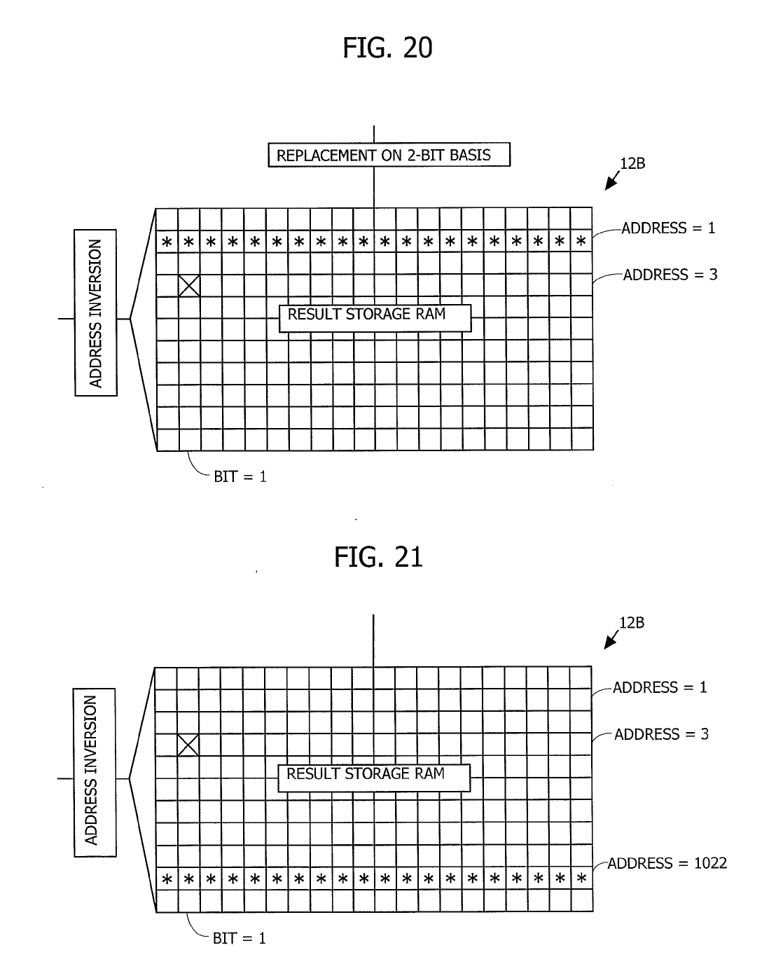

In this status, when transferring the result of the testing target RAM 12A to the result storage RAM 12B and reading the data of the result storage RAM 12B, the data as in FIG. 20 are obtained. To be specific, a result with a mixture of the fault of the testing target RAM 12A and the fault of the result storage RAM 12B is acquired. Accordingly, it is difficult to separate the mixed results by reading the data of the result storage RAM 12B.

Thereupon, the test control circuit 11 next performs the address conversion by the address conversion unit 122 of the result storage RAM 12B, and transfers the result read from the testing target RAM 12A to the result storage RAM 12B.

FIG. 21 illustrates an example of the results stored in the result storage RAM 12B when the address conversion unit 122 conducts the address inversion. With the address conversion by the address conversion unit 122, the word line specified by the address=1 (the second line counted from the uppermost) is converted into the word line (the second line counted from the lowest) specified by the address=1022. In the example of FIG. 21, the word line containing the fault data existing in the word line 1 before the address conversion is shifted to the word line specified by the address=1022. Therefore, the fault data of the portion notated by “*” indicating the shift to the address=1022 are determined to be the fault data transferred from the testing target RAM. On the other hand, the fault data existing in the portion specified by the address=3 and the bit=1 remain unshifted before and after the address conversion. Hence, the fault of the portion indicated by “x” with no shift before and after the address conversion is deemed to be the fault inherent in the result storage RAM 12B.

Accordingly, what the fault “x” of the result storage RAM 12B is removed from the test result acquired out of the result storage RAM 12B in FIG. 20 becomes the test result of the testing target RAM 12A.

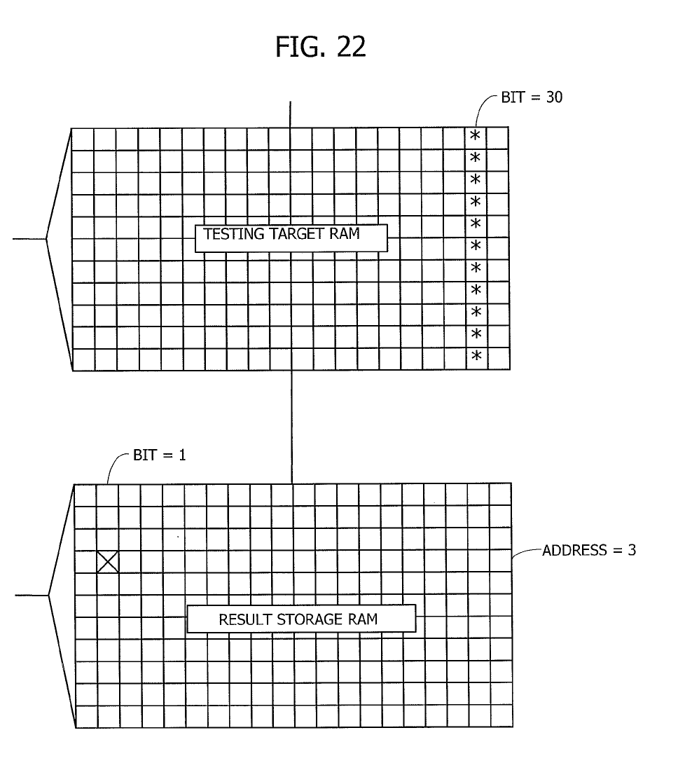

Next, the bit line fault is considered. FIG. 22 depicts an example of the bit line fault. In FIG. 22, the testing target RAM 12A has a portion of the bit line fault specified by the bit=30. Furthermore, the result storage RAM 12B has the single cell fault specified by the address=3 and the bit=1.

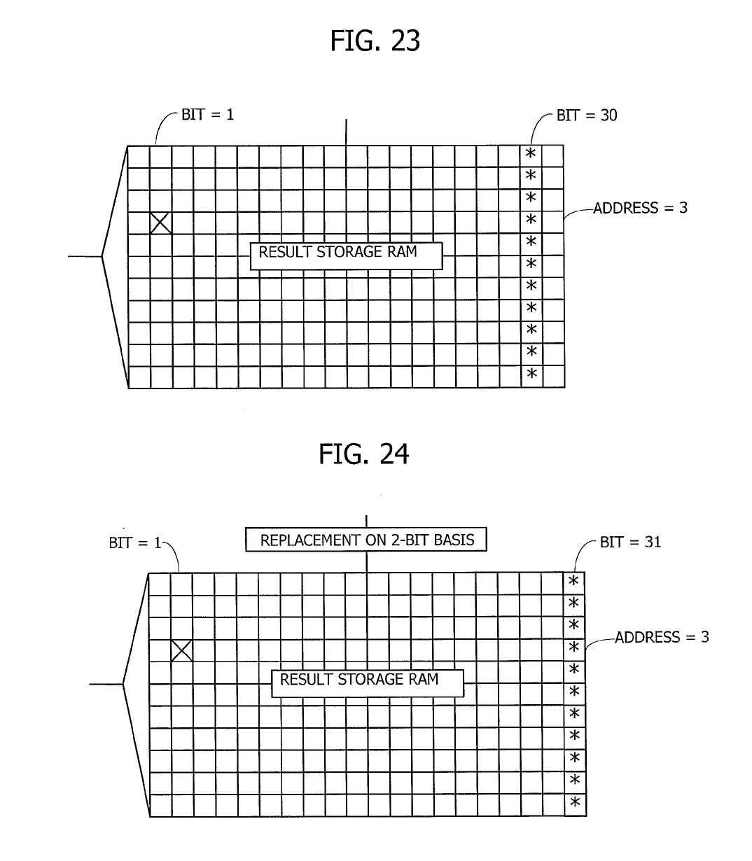

FIG. 23 illustrates a result given by reading the write result of the test pattern to the testing target RAM 12A and transferring the write result to the result storage RAM 12B. As in FIG. 23, there are obtained the data of a mixture of the fault of the testing target RAM 12A and the fault of the result storage RAM 12B.

FIG. 24 illustrates a result given when the data conversion unit 124 replaces the data on the 2-bit basis and transfers the data. With the bit conversion, the bit line specified by the bit=30 (the second column from the right in FIG. 24) is converted into the bit line specified by the bit=31 (the rightmost column in FIG. 24). In FIG. 24, the fault data are shifted from the bit line specified by the bit=30 to the bit line specified by the bit=31. Therefore, the LSI tester 2 can determine that the fault data of the portion shifted to the bit=31 indicated by “*” are the fault data transferred from the testing target RAM 12A. On the other hand, in the faults in FIG. 24, the fault specified by the address=1 and the bit=1 is not shifted. Therefore, the LSI tester 2 can determine that the fault of the unshifted portion (cell) indicated by “*” is the fault inherent in the result storage RAM 12B. Hence, the LSI tester 2 can obtain what the fault (indicated by “*” in FIG. 24) in the result storage RAM 12B is removed from the result in FIG. 24 as the test result of the testing target RAM 12A.

If the fault is neither the word line fault nor the bit line fault but spreads lengthwise and crosswise over the memory cells, there exists a possibility that the areas before and the after the conversion are to be superposed on each other. The “fault spreading lengthwise and crosswise over the memory cells” connotes a case where at least any one of the plurality of word line faults and the plurality of bit line faults occurs. In this case, it is unfeasible to distinguish between the faults of the testing target RAM 12A and the faults of the result storage RAM 12B as the case may be.

In the case of the fault spreading lengthwise and crosswise over the memory cells, however, there are many cases where the fault is empirically detected even in the operation at the slow speed. This being the case, the fault spreading lengthwise and crosswise over the memory cells can undergo the sufficient test even in the case of implementing the low-speed FBM solely in the testing target RAM 12A without exploiting the transfer at the actual speed to the result storage RAM 12B. Herein, the “low-speed FBM” connotes generating the FBM based on not reading from the testing target RAM 12A by use of the clock signals at the actual speed as by the PLL 16 but reading from the testing target RAM 12A via the internal register, e.g., the result register 15 of the LSI1B from the LSI tester 2.

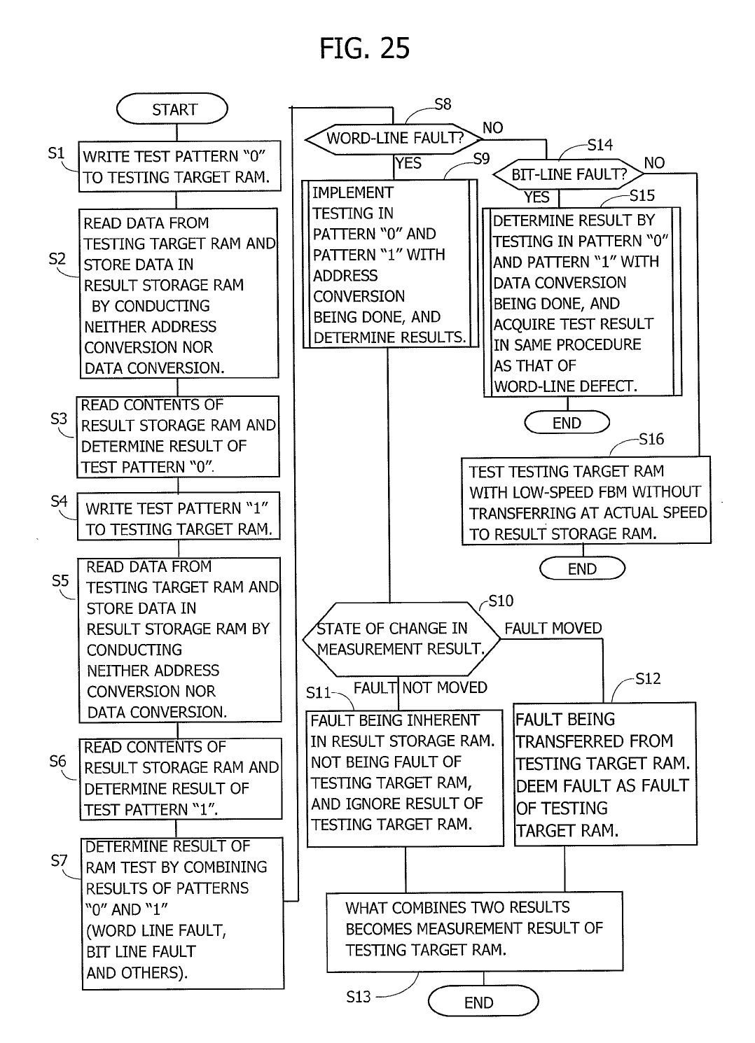

FIG. 25 illustrates a processing flow of the test conducted by the LSI tester 2 and the test control circuit 11. A start of processes in FIG. 25 is triggered by such an event that the LSI tester 2 writes the testing data 22 to the LSI1B and initiates the test. In the respective processes of FIG. 25, e.g., S1-S6 are the processes of the test control circuit 11, and S7-S16 are the processes of the LSI tester 2. Upon the initiation of the test, to begin with, the test control circuit 11 writes the test pattern “0” to the testing target RAM 12A (S1).

Next, the test control circuit 11 reads the stored data from the testing target RAM 12A. Then, the test control circuit 11 stores the readout data in the result storage RAM 12B by conducting neither the address conversion nor the data conversion (S2). Subsequently, the test control circuit 11 reads the contents of the result storage RAM. Then, the test control circuit 11 determines whether the test pattern “0” is read or not (S3). In this case, the test control circuit 11 stores the test pattern “0” as the expected values in the register 13. Subsequently, in the test control circuit 11, the comparator 14 compares the contents read from the result storage RAM with the expected values. A comparison result is handed over to the LSI tester 2 via the result register.

Next, the test control circuit 11 writes the test pattern “1” to the testing target RAM 12A (S4). Subsequently, the test control circuit 11 reads the stored data from the testing target RAM 12A. Then, the test control circuit 11 stores the readout data in the result storage RAM 12B by conducting neither the address conversion nor the data conversion (S5). Subsequently, the test control circuit 11 reads the contents of the result storage RAM. Then, the test control circuit 11 determines whether the test pattern “1” is read or not (S6). The determination procedure in S6 is the same as S3. The comparison result is handed over the LSI tester 2 via the result register.

Next, the LSI tester 2 determines the RAM test result by adding the results of the test patterns “0” and “1” together (S7). The LSI tester 2 determines whether the word line fault exists or not by determining, e.g., whether or not the plurality of errors occurs in the word direction at the same address. Further, the LSI tester 2 determines whether the bit line fault exists or not by determining, e.g., whether or not the errors occur over the plurality of word lines in the same bit line position. Alternatively, the LSI tester 2 determines, if the word line faults and the bit line faults occur batchwise, whether or not a part or all of the RAM areas suffer the faults in a range having square dimensions.

Then, in the case of the word line fault (Yes in the determination of S8), the LSI tester 2 advances the control to S9. However, if only the word line fault occurs but the bit line fault does not occur, the determination “Yes” is made in S8. Namely, if the word line fault and the bit line fault exist in mixture, the faults undergo a further determination in S14 and are treated in another process (S16).

If the determination “Yes” is made in S8, the LSI tester 2 deems that the address conversion is performed when stored in the result storage RAM 12B, then sets the testing data 22 so as to execute again the processes in S1-S6 with respect to the test patterns “0” and “1”, and initiates the test by use of the test control circuit 11 (S9). Then, the LSI tester 2 determines the status of the measurement result (S10). That is, the LSI tester 2 determines whether or not the address of the word line fault changes as a result of storing the data, with the address conversion being performed, read from the testing target RAM in the result storage RAM 12B.

As a result of S10, if the position of the word line fault does not shift, the LSI tester 2 determines that there exists the fault inherent in the result storage RAM 12B (S11). Accordingly, the word line fault specified in S7 and S8 is determined not to be the fault of the testing target RAM 12A. As a result of S10, whereas if the position of the word line fault shifts, the LSI tester 2 determines that an error exists in the data transferred from the testing target RAM 12A. Accordingly, the LSI tester 2 determines that the fault exists in the testing target RAM 12A. These determinations are made with respect to both of the test patterns “0” and “1”. Next, the LSI tester 2 adds together the results in S11 and S12, thus setting these results as the measurement result of the testing target RAM (S13). Note that the fault portion of the result storage RAM 12B can be specified from the results in S11 and S12. Namely, as the result of S10, if the position of the word line fault does not shift, the fault word portion in the address on the non-shifted word line or the fault bit portion can be determined to be the fault position of the result storage RAM 12B.

Further, if it is determined in S8 that the word line fault does not exist, the LSI tester 2 determines whether the bit line fault exists or not (S14). Herein, as for the determination in S14, if the word line fault does not exist but only the bit line fault occurs, the determination “Yes” is made in S14. That is, if the word line fault and the bit line fault exist in mixture, the faults are treated in another process (S16). Note that the bit line fault contains the single bit fault in the determination in S14. Namely, the LSI tester 2 treats the one bit fault in the one address as the bit line fault.

If the bit line fault exists, the LSI tester 2 deems that the address conversion is performed when stored in the result storage RAM 12B, then sets the testing data 22 so as to execute again the processes in S1-S6 with respect to the test patterns “0” and “1”, and initiates the test by use of the test control circuit 11 (S15).

Then, the LSI tester 2 determines the status of the measurement result. Namely, the LSI tester 2 determines whether or not the bit line position of the bit line fault shifts as a result of storing the data, with the address conversion being performed, read from the testing target RAM 12A in the result storage RAM 12B. As a result of the determination, if the bit line position of the bit line fault does not shift, the LSI tester 2 determines that there exists the fault inherent in the result storage RAM 12B.

While on the other hand, as a result of the determination, if the bit line position of the bit line fault shifts, the LSI tester 2 determines that an error exists in the data transferred from the testing target RAM 12A. Accordingly, the LSI tester 2 determines that the fault exists in the testing target RAM 12A.

If the determination in S14 indicates neither the bit line fault nor the word line fault, the LSI tester 2 executes a process in 516. In the process in 516, the LSI tester 2 does not execute the processes in S1-S6, i.e., neither reads the data from the testing target RAM 12A at the actual speed nor initiates the test which involves storing the data in the result storage RAM 12B at the actual speed. In place of S1-S6, the LSI tester 2 tests the testing target RAM 12A with the low-speed FBM (S16). The “low-speed FBM” connotes a process of, e.g., as illustrated in FIG. 2, reading the data from the testing target RAM 12A and thus generating the FBM by use of the internal register of the LSI1B.

As discussed above, in the LSI1B including the test control circuit 11 in the Example 2, the LSI tester 2 reads the data from the testing target RAM 12A at the actual speed and initiates the test which involves storing the data in the result storage RAM 12B by use of the test control circuit 11. Then, the LSI tester 2 determines from the test result whether the word line error and the bit line error occur or not. Subsequently, if the word line error occurs, the LSI tester 2 performs the address conversion with respect to the data read from the LSI tester 2, and initiates the test which involves storing the data in the result storage RAM 12B by use of the test control circuit 11. Then, depending on whether the address conversion is performed or not, if there is a shift of the address of the error portion in the result storage RAM 12B, the LSI tester 2 determines the error to be the error existing in the testing target RAM 12A.

Moreover, if the test result indicates the bit line error, the LSI tester 2 performs the data conversion of the data read from the testing target RAM 12A, and initiates the test which involves storing the data in the result storage RAM 12B by use of the test control circuit 11. Then, depending on whether the data conversion is performed or not, if there is a shift of the bit line position of the error portion in the result storage RAM 12B, the LSI tester 2 determines the error to be the error existing in the testing target RAM 12A.

Thus, according to the LSI1B in the example 2, in the test for the testing target RAM 12A at the actual speed, it is feasible to distinguish between the error occurring in the testing target RAM 12A and the error occurring in the result storage RAM 12B without providing the dedicated standby area in the result storage RAM 12B. Note that if there is at least one RAM device becoming the result storage RAM 12B, the processes in FIG. 25 are repeatedly executed with respect to the RAM device having the same capacity as or the capacity smaller than the capacity of the RAM device becoming the result storage RAM 12B, thereby enabling all the RAM devices to be tested. Namely, the processes in FIG. 25 are executed, and hence it may be sufficient to provide at least one RAM device capable of the address conversion and the data conversion.

Moreover, in the case of setting the RAM device itself used as the result storage RAM 12B to the testing target, it may be sufficient to provide further one RAM device becoming the result storage RAM 12B. Address conversion circuits and data conversion circuits may also, however, be provided in all the RAM devices built in the LSI1.

Further, in FIG. 25, the description is made on the assumption that the LSI tester 2 executes the processes in S7-S16. It does not, however, mean that the RAM testing method in the Example 2 is limited to the processes explained in FIG. 25. For instance, the test control circuit 11 may also execute a part or all of the processes in S7-S16 of FIG. 25.

For example, the test control circuit 11 may incorporates a control unit including the CPU and the main storage device and capable of executing the computer program. Then, the control unit within the test control circuit 11 may also execute a part or all of the processes in S7-S16 of FIG. 25. In this case, it may be sufficient that for the LSI tester 2 to hand over the testing data 22 to the control unit within the test control circuit 11 and receive the test result.

### Example 3

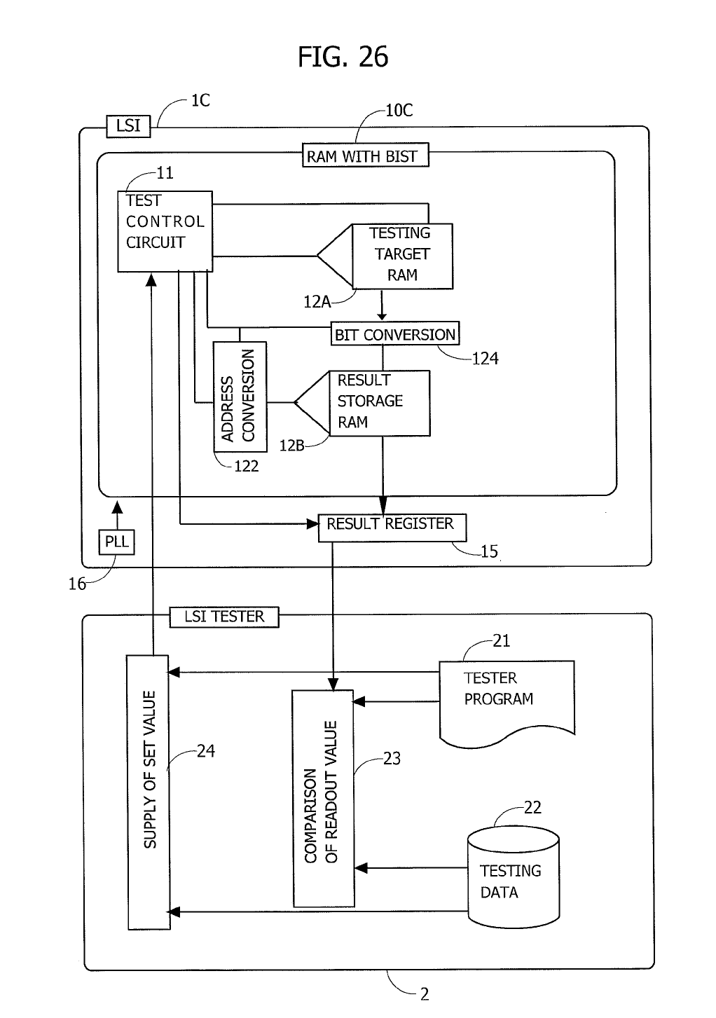

A third working example (Example 3) exemplifies the RAM testing method based on the BIST with no comparator. FIG. 26 illustrates RAM testing procedures based on the BIST with no comparator. A configuration and the procedures in the Example 3 are the same as those in the Example 2 except using the BIST with no comparator. This being the case, the same components as those in the Example 2 are marked with the same numerals and symbols, and their explanations are omitted. As in FIG. 26, the Example 3 exemplifies an LSI1C including a RAM 10C with no comparator. The RAM 10C with no comparator is different in terms of having none of the comparator 14 as compared with FIG. 15. The procedures in the Example 3 will hereinafter be described according to FIG. 26.

(1) The LSI tester 2 writes the testing data 22 to the LSI1C in accordance with the tester program 21. Further, the LSI tester 2 reads the values in the internal result register 15 from the LSI1C, and compares the readout values with the testing data. Any inconvenience might not be caused if the LSI tester 2 performs the writing and reading operations not at an operating speed of the LSI but at a low speed.
(2) The test control circuit 11 supplies the control signal and the testing data related to the test to a testing target circuit. The operation of the test control circuit 11 is determined based on setting values written by the LSI tester 2.
(3) The testing target RAM 12A performs the testing operation based on the control signal and the testing data given from the test control circuit 11. The testing operation is conducted at the LSI actual speed. Clocks of the actual speed are supplied from the PLL 16.
(4) The result storage RAM 12B, the address conversion unit 122 and the bit conversion unit 124 transfer the contents of the testing target RAM 12A to the result storage RAM 12B in accordance with the control signals given from the test control circuit 11. The transfer thereof is performed at the LSI actual speed. Further, a determination as to whether the address conversion unit 122 and the bit conversion unit 124 perform the converting operations is controlled by the control signals given from the test control circuit 11. Moreover, the control signals given from the test control circuit 11 are set by the testing data 22 coming from the LSI tester 2.
(5) The result register 15 gets stored with the readout values from the result storage RAM 12B through the control signal given from the test control circuit 11. The LSI tester 2 acquires the readout values from the result storage RAM 12B via the result register 15. Any inconvenience might not be caused by performing the operations of reading the data from the result storage RAM 12B and acquiring the readout values by the LSI tester 2 via the result register 15 at the low speed.
(6) The LSI tester 2 compares the test result read from the result storage RAM 12B via the result register 15 with the expected values based on the testing data 22. As a result, the LSI tester 2 determines whether the word line fault exists or not with respect to the test patterns “0” and “1” respectively and, if the word line fault exists, determines whether the address of the word line fault changes or not on the basis of whether the address conversion is conducted or not. Then, the LSI tester 2, if the address of the word line fault changes on the basis of whether the address conversion is conducted or not, determines the fault to be the fault in the testing target RAM 12A.

Further, the LSI tester 2 determines whether the bit line fault exists or not with respect to the test patterns “0” and “1” respectively and, if the bit line fault exists, determines whether the bit line position of the bit line fault shifts or not on the basis of whether the data conversion is conducted or not. Then, the LSI tester 2, if the bit line position of the bit line fault shifts on the basis of whether the data conversion is conducted or not, determines the fault to be the fault in the testing target RAM 12A.

As discussed above, also with the LSI1C including the RAM 10C with no comparator, similarly to the Example 2, in the test for the testing target RAM 12A at the actual speed, it is feasible to distinguish between the error caused in the testing target RAM 12A and the error caused in the result storage RAM 12B without providing the dedicated standby area in the result storage RAM 12B.

### Example 4

<Installation of Row and Column>

If the capacity of the RAM increases and when the cells are disposed on a word line basis in the RAM, a lengthwise/crosswise size (aspect ratio) of the RAM area gets ill-balanced. For example, in the case of the RAM having a capacity of (1024×72) bits, when simply disposing the RAM cells two-dimensionally, it follows that the 1024 RAM cells are disposed lengthwise, while the 72 RAM cells are disposed crosswise, which layout appears long in the lengthwise direction.

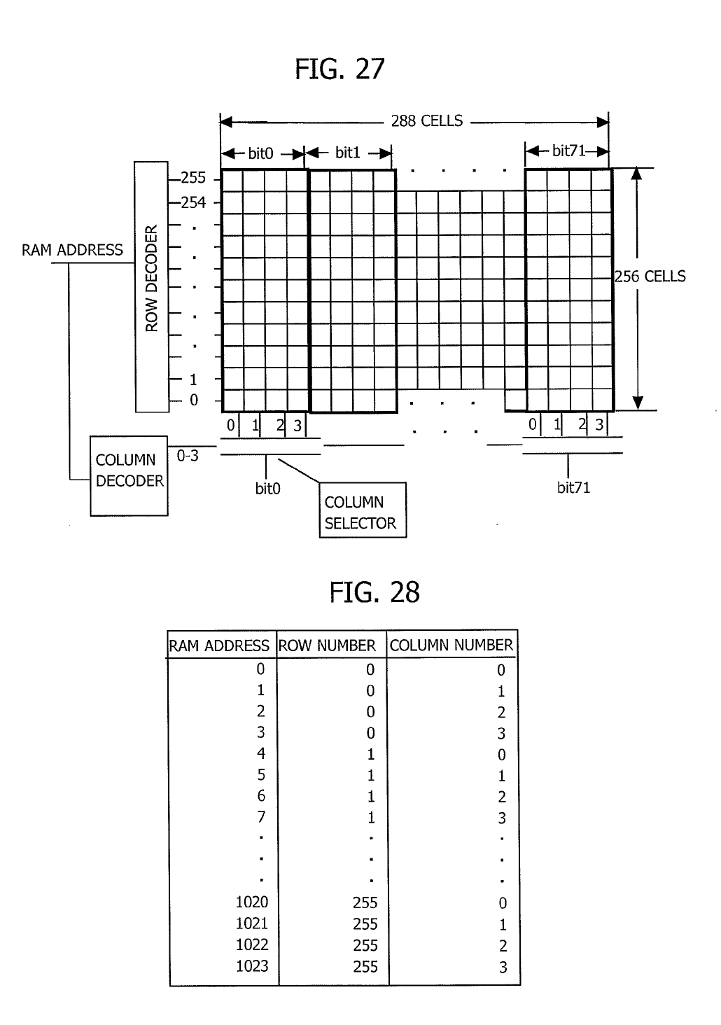

Avoidance of the elongated RAM area involves taking a technique of separating the addresses in row and in column. For instance, in the case of 1024 addresses, these 1024 addresses are separated into rows=256 and columns=4. The address is expressed by a combination of the row and the column, and therefore the 1024 addresses can be expressed such as 256×4=1024. FIG. 27 illustrates the RAM area with the rows=256 and the columns=4.

RAM addresses 0-1023 are separated into row numbers and column numbers, thereby having an access to RAM cells/arrays. Namely, a row decoder determines an access line to the row specified by the row number, thus selecting the row. Furthermore, a column decoder determines an access line to a column specified by the column number, thus selecting the column. In this way, the address is established by the row number and the column number, and a bit string of the relevant address is accessed.

FIG. 28 illustrates how the RAM addresses, the row numbers and the column numbers are associated with each other. Such a structure being adopted, the layout of the RAM cells has 256 cells lengthwise and 288 cells crosswise and can be thus well-balanced. In the following Example 4, such a case is considered that the address conversion using the address inversion and the bit conversion using the replacement on the 2-bit basis described in the Examples 1-3 are applied to the RAM containing the rows and the columns in FIG. 28.

<Relation Between Address Conversion and Row>

The address conversion is an expedient for avoiding the defect of the word line, however, the word line defect becomes a row defect in the RAM having the row/column structure. It is herein considered how the row number is converted through the address conversion. In an associative table of FIG. 28, a row number 0 is validated by accessing RAM addresses 0-3, and hence a defect of the row 0 appears to be a defect of the RAM addresses 0-3. Herein, when performing the address conversion based on the address inversion, the RAM addresses 0-3 are converted into RAM addresses 1023-1020. The RAM addresses 1023-1020 are associated with a row number 255.

It therefore follows that the row number 0 is converted into the row number 255. Similarly, a row number 1 is converted into a row number 254, and the row number 255 is converted into the row number 0, thus satisfying a condition of the address conversion without indicating the same row number before and after the conversion.

<Bit Conversion>

In the RAM having the row/column structure, one bit is structured by four columns. Herein, in the case of conducting a bit conversion through the replacement on the 2-bit basis, the replacement occurs on the basis of 1 bit=4 columns. These four columns are not overlapped with each other. Hence, there are no columns existing in the same position before and after the conversion, whereby a condition of the bit conversion is satisfied.

From what has been described so far, the address conversion based on the address inversion and the bit conversion through the replacement on the 2-bit basis satisfy the condition “the conversion not being converted in the same position before and after the conversion”, thereby enabling the fault to be avoided.

### Example 5

In the Example 2 described above, for instance, as illustrated in FIG. 17, the bits of all the addresses are inverted when performing the address conversion. It does not, however, mean that the address conversion is limited to the configuration of the Example 2. In short, it may be sufficient to shift all the addresses of the RAM devices, in other words, all the word lines of the result storage RAM 12B before and after the address conversion.

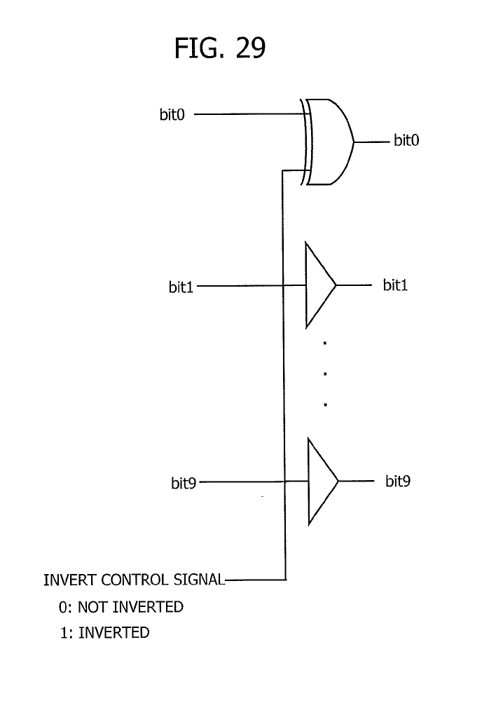

FIG. 29 depicts another example of the address conversion to shift all the word lines of the result storage RAM 12B. In a fifth working example (Example 5), according to the address converting method, one arbitrary of the respective bits of the address is inverted. FIG. 29 illustrates a configuration to invert the bit “0”. Namely, an exclusive OR gate is inserted in the bit “0”, and a determination as to whether the inversion is conducted or not is controlled by an invert control signal. The bit to be inverted may be one arbitrary bit, however, it does not mean that the bit to be inverted is limited to the bit “0”. Moreover, it does not happen that the address after the conversion takes the same value as the value before the conversion due to the address conversion that involves inverting one arbitrary bit such as this. In the configuration of the Example 5, the address conversion can be attained with a smaller number of gates than in the Example 2.

### Effects of the Examples 1-5

The FBM can be acquired at the actual speed by writing the result of the testing target RAM 12A to the result storage RAM 12B with the clock signals of the PLL 16. In such a test at the actual speed:

(1) the word line fault of the result storage RAM 12B is avoided by providing the address conversion unit 122 in the result storage RAM 12B; and
(2) the bit line fault of the result storage RAM 12B by providing the data conversion unit 124 in the result storage RAM 12B.

With an addition of the two configurations described above, the test exhibiting the high reliability at the actual speed can be attained without using the dedicated RAM having the standby region for avoiding the fault in the result storage RAM 12B.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A testing method by which a testing apparatus tests a memory mounted on a semiconductor integrated circuit including a testing circuit, the method comprising:
writing testing data to a testing target area of the memory by the testing circuit;
reading the written data from the testing target area of the memory by the testing circuit;
writing the data read from the testing target area of the memory to a result storage area of the memory with a first data layout by the testing circuit;
acquiring a first comparison result by reading the data written to the result storage area of the memory and comparing the readout data with check data;
rewriting the data read from the testing target area of the memory to the result storage area of the memory in a way that changes a writing destination with a second data layout different from the first data layout within the result storage area of the memory by the testing circuit;
acquiring a second comparison result by reading the data rewritten to the result storage area of the memory and comparing the readout data with the check data; and
specifying a defective position of the memory in accordance with the first comparison result and the second comparison result.

2. The testing method according to claim 1, wherein the specifying includes specifying, when the defective position in the first comparison result is coincident with the defective position in the second comparison result, a defective position in result storage area of the memory and specifying, when the defective position in the first comparison result is not coincident with the defective position in the second comparison result, a defective position in the testing target area of the memory.

3. The testing method according to claim 1, wherein the reading of the data from the testing target area and the writing of the data to the result storage area are performed at an operation frequency when in a normal operation of the memory, and
the reading of the data from the result storage area is performed at an operation frequency lower than the operation frequency when writing the data to the result storage area.

4. A semiconductor integrated circuit comprising:
a memory;
a testing circuit to execute testing the memory; and
a converting unit to convert a data writing destination so that the data layout within the result storage area becomes the first data layout or the second data layout when writing the data read from the testing target area of the memory to the result storage area of the memory.

5. The semiconductor integrated circuit according to claim 4, wherein the memory includes a plurality of memory devices,
the testing target area is one device of the plurality of memory devices, and
the result storage area is another device of the plurality of memory devices.
